(19) United States
(12) Patent Application Publication
(10) Pub. No.: US 2008/0069197 A1
(43) Pub. Date: Mar. 20, 2008

(54) EQUALIZER FOR EQUALIZING MULTIPLE RECEIVED VERSIONS OF A SIGNAL

(75) Inventors: Adriel P. Kind, Macquarie Park (AU); Graeme K. Woodward, Epping (AU)

Correspondence Address: MENDELSOHN & ASSOCIATES, P.C., 1500 JOHN F. KENNEDY BLVD., SUITE 405, PHILADELPHIA, PA, 19102, US

(73) Assignee: AGERE SYSTEMS INC., Allentown, PA (US)

(21) Appl. No.: 11/782,845

(22) Filed: Jul. 25, 2007

Related U.S. Application Data
(60) Provisional application No. 60/826,280, filed on Sep. 20, 2006.

(51) Int. Cl. H03K 5/159

(52) U.S. Cl. 375/232

(57) ABSTRACT

In one embodiment, an equalizer equalizes two versions of a signal that are received through separate propagation paths, to generate one equalized signal. The equalizer comprises a single FIR filter and an NLMS updater. During each iteration, the NLMS updater supplies a set of coefficients to the FIR filter. The FIR filter processes samples of both the first and second versions by multiplying each sample by one coefficient in the set of coefficients to generate a number of products. The products are combined by a summation block to generate an equalized sample. The equalized sample is compared to a reference signal to generate an error measure used to update the set of coefficients. The samples of the received versions are then advanced and this process is repeated to generate further equalized samples. In further embodiments, the equalizer may process more than two versions of a signal.

### CROSS-REFERENCE TO RELATED APPLICATIONS

This application claims the benefit of the filing date of U.S. provisional application No. 60/826,280, filed on Sep. 20, 2006 as attorney docket no. Kind 5-6, the teachings of which are incorporated herein by reference.

The subject matter of this application is related to PCT patent application no. PCT/US07/00622 filed 10 Jan. 2007 as attorney docket no. Banna 3-2-2-3, U.S. patent application Ser. No. 11/710,212 filed 23 Feb. 2007 as attorney docket no. Cooke 2-7-4, and U.S. patent application Ser. No. 11/731,173 filed 30 Mar. 2007 as attorney docket no. Sontowski 4-7, the teachings of all of which are incorporated herein by reference.

### BACKGROUND OF THE INVENTION

1. Field of the Invention

The present invention relates to signal processing receivers, and, more specifically, to methods and apparatuses for equalizing signals received by such devices.

2. Description of the Related Art

In communication systems, a transmitted signal may be altered due to effects of fading, noise, or other interference. These effects reduce the quality of the received signal, and as a result, a receiver may experience errors in recovering the transmitted data. In order to combat errors that result from these effects, a receiver may employ multiple antennas to improve the reliability of the receiver. In such a receiver, each antenna might receive a different version of the transmitted signal due to differences in transmission paths. As the versions experience fading and other effects independently of each other, correlation between the versions decreases. The degree of correlation is generally affected by factors such as antenna spacing, carrier frequency, and individual radiation patterns. Reliability of the receiver may be improved by minimizing the correlation between multiple versions of the received signal. When one antenna is experiencing a poor signal, one or more other antennas might be experiencing a higher-quality signal. These signals may then be equalized separately and combined into one signal. When combined appropriately, the resulting signal quality is better than that of each individual signal.

### SUMMARY OF THE INVENTION

Problems in the prior art are addressed in accordance with the principles of the present invention by jointly equalizing two or more versions of a signal. By performing equalization in this manner, the receiver can take into account the correlation of the two or more versions during equalization. Furthermore, performing equalization in this manner reduces the need to perform post-equalization processing for each equalized version, parameter estimation, and combining downstream of the equalizer. This reduction in processing can lead to significant savings in computational and implementation complexity.

In one embodiment, the present invention is a method for equalizing at least a first and a second version of a signal transmitted through two or more different transmission paths. The method may include filtering the first version based on a first subset of filter coefficients and the second version based on a second subset of filter coefficients to generate an equalized signal. An error measure is calculated based on the equalized signal, and the first and second subsets of filter coefficients are adaptively updated based on the error measure.

In another embodiment, the present invention is an apparatus for performing the method described in the previous paragraph. The apparatus may include a filter, an error calculator, and a coefficient updater. The filter is adapted to filter the first version based on a first subset of filter coefficients and the second version based on a second subset of filter coefficients to generate an equalized signal. The error calculator is adapted to calculate an error measure based on the equalized signal. The coefficient updater is adapted to adaptively update the first and second subsets of filter coefficients based on the error measure.

In another embodiment, the present invention is a method for equalizing two or more versions of a signal transmitted through two or more different transmission paths. The method may include applying two or more adaptive sub-filters to the two or more versions to generate two or more sub-filtered signals. The two or more sub-filtered signals are combined to generate an equalized output signal for the two or more versions, and the two or more adaptive sub-filters are updated based on the equalized output signal.

In yet another embodiment, the present invention is an apparatus for performing the method described in the previous paragraph. The apparatus may include two or more adaptive sub-filters, a combining block, and a coefficient updater. The two or more adaptive sub-filters are adapted to generate two or more sub-filtered signals from the two or more versions. The combining block is adapted to combine the two or more sub-filtered signals to generate an equalized output signal for the two or more versions. The coefficient updater is adapted to update the two or more adaptive sub-filters based on the equalized output signal.

### BRIEF DESCRIPTION OF THE DRAWINGS

Other aspects, features, and advantages of the present invention will become more fully apparent from the following detailed description, the appended claims, and the accompanying drawings in which like reference numerals identify similar or identical elements.

FIG. 1 shows a simplified block diagram of one embodiment of a receiver having a single antenna;

FIG. 2 shows a simplified block diagram of one embodiment of a receiver having two antennas;

FIG. 3 shows a simplified block diagram of a receiver having two antennas according to one embodiment of the present invention; and

FIG. 4 shows a simplified block diagram of a receiver having three antennas according to another embodiment of the present invention.

### DETAILED DESCRIPTION

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

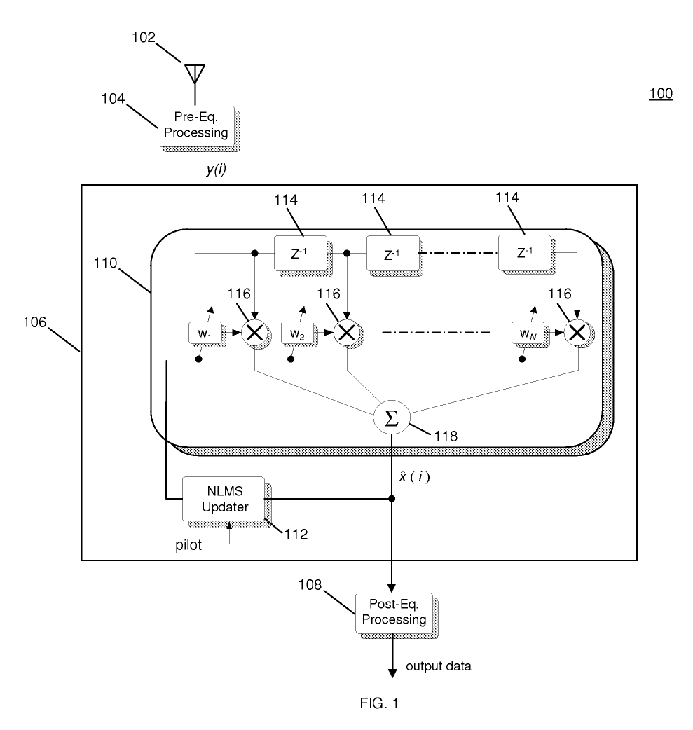

FIG. 1 shows a simplified block diagram of one embodiment of a receiver 100 having a single antenna. Receiver 100 receives a signal using antenna 102 and performs pre-equalization processing 104, which might include radio-frequency de-modulation, analog-to-digital conversion, synchronization, or other processing to generate and prepare pre-processed signal y(i) for equalization. Pre-processed signal y(i) is provided to normalized-least-mean-squares (NLMS) equalizer 106, which equalizes the signal to generate equalized signal x(i). Equalized signal x(i) is then provided to post-equalization processing 108, which might include de-scrambling, de-spreading, symbol estimation, data symbol de-mapping, or other processing for recovering one or more output data streams from the received signal.

NLMS equalizer 106 equalizes pre-processed signal y(i) using FIR filter 110 and NLMS coefficient updater 112. During each iteration, FIR filter 110 processes N samples of pre-processed signal y(i) using a set of NLMS coefficients (e.g., w(i)=w₁(i), w₂(i), . . . ,w_{N}(i)) provided by NLMS coefficient updater 112. Specifically, during each iteration, a new sample of y(i) is added to a tapped delay line, comprising N-1 delay elements 114 such that each sample, excluding the first sample, has been delayed by one or more delay elements 114. The N samples are provided to N multipliers 116, where each multiplier multiplies the corresponding sample by a corresponding NLMS coefficient from the set of NLMS coefficients w(i). The products generated by the N multipliers 116 are then added together by summation block 118 to generate a sample of equalized signal \hat{x}(i). By the time that an equalized sample is generated, the samples of pre-processed signal y(i) have been advanced by one delay element 114 within the tapped delay line. The set of NLMS coefficients w(i) received from NLMS coefficient updater 112 is then updated for the next iteration using the N most recent samples of equalized signal \hat{x}(i). This process is repeated to equalize further samples of pre-processed signal y(i).

NLMS coefficient updater 112 updates the set of NLMS coefficients using the equalized samples output from FIR filter 110. First, during each iteration, the sample of equalized signal \hat{x}(i) output from summation block 118 is compared to a reference signal x(i) to generate an error as shown in Equation (1) below:

e(i)=\hat{x}(i)−x(i). (1)

The reference signal represents the ideal value for the received signal, assuming no adverse effects from transmission. In conventional applications, a portion of the transmitted signal is not known by the receiver. However, a pilot signal z(i), which contains a known sequence of bits, may be transmitted for training and tracking purposes. Thus, equalized signal \hat{x}(i) may be compared to the known pilot signal z(i) to determine an error measure ê(i) that approximates the true error e(i) as shown in Equation (2):

e(i)≈ê(i)=\hat{x}(i)−z(i). (2)

Next, each updated NLMS coefficient wⱼ(i+1) in the set is calculated based on the prior NLMS coefficient wⱼ(i) for the corresponding tap j and pre-processed signal vector y(i) using an NLMS calculation such as that shown in Equation (3):

$${w}_{j} ( i + 1 ) = {w}_{j} ( i ) - \tilde{Δ} \frac{{y}_{j} ( i ) {\hat{e}}^{*} ( i )}{{‖ y ( i ) ‖}^{2}} , for j = 1 , 2 , … , N \qquad ( 3 )$$

where, \tilde{Δ} is a step size, yⱼ(i) is the sample of vector y(i) corresponding to tap j, ê*(i) is the complex conjugate of error measure ê(i), and ∥y(i)∥ is the magnitude of vector y(i).

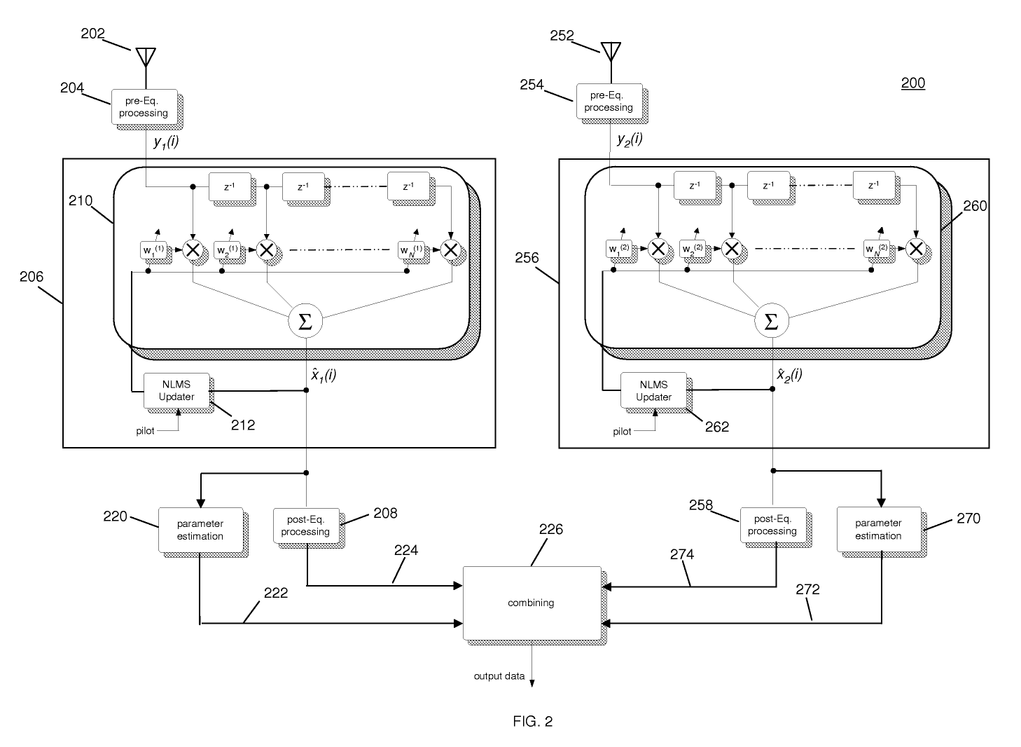

FIG. 2 shows a simplified block diagram of one embodiment of a receiver 200 having two antennas. Antenna 202 receives a first version of a transmitted signal and processes the first version using a first equalization chain. The first equalization chain comprises pre-equalization processing 204, NLMS equalizer 206, post-equalization processing 208, and parameter estimation 220. Pre-equalization processing 204 and NLMS equalizer 206 perform operations analogous to those of pre-equalization processing 104 and NLMS equalizer 106 of receiver 100 of FIG. 1 to generate a first equalized signal \hat{x}₁(i). The first equalized signal \hat{x}₁(i) is then provided to post-equalization processing 208 and parameter estimation 220. Post-equalization processing 208 performs operations, depending on the modulation employed by the transmitter, to prepare the first equalized signal \hat{x}₁(i) for combining. For example, in code-division-multiple-access (CDMA) applications, such processing might include de-scrambling, de-spreading, or other processing. Parameter estimation 220 estimates parameters 222 used for combining, such as received signal power and signal-to-noise ratio (SNR). The prepared equalized signal 224 and the estimated parameters 222 are then provided to maximal ratio combining (MRC) block 226.

Antenna 252 receives a second version of the transmitted signal which is transmitted over a propagation path different from that of the first received version. The second version is processed independent of the first version using a second processing chain. The second processing chain comprises pre-equalization processing 254, NLMS equalizer 256, post-equalization processing 258, and parameter estimation 270, which perform operations analogous to those of the equivalent processing of the first processing chain to generate a second prepared equalized signal 274 and a second set of estimated parameters 272. The second prepared equalized signal 274 and second set of estimated parameters 272 are provided to MRC block 226 which combines the equalized signals from the first and second processing chains to generate a higher-quality received signal (e.g., having a higher SNR).

Receiver 200 equalizes the two versions of the signal using separate equalizers, prepares the two equalized versions using separate post-equalization processing and separate parameter estimation, and combines the two prepared versions. By performing equalization in this manner, receiver 200 does not take into account the correlation of the two versions during equalization, and thus, equalization is not optimal. Further, when the two versions are highly correlated, the accuracy of the combining process is typically reduced, resulting in a significant degradation in performance of receiver 200.

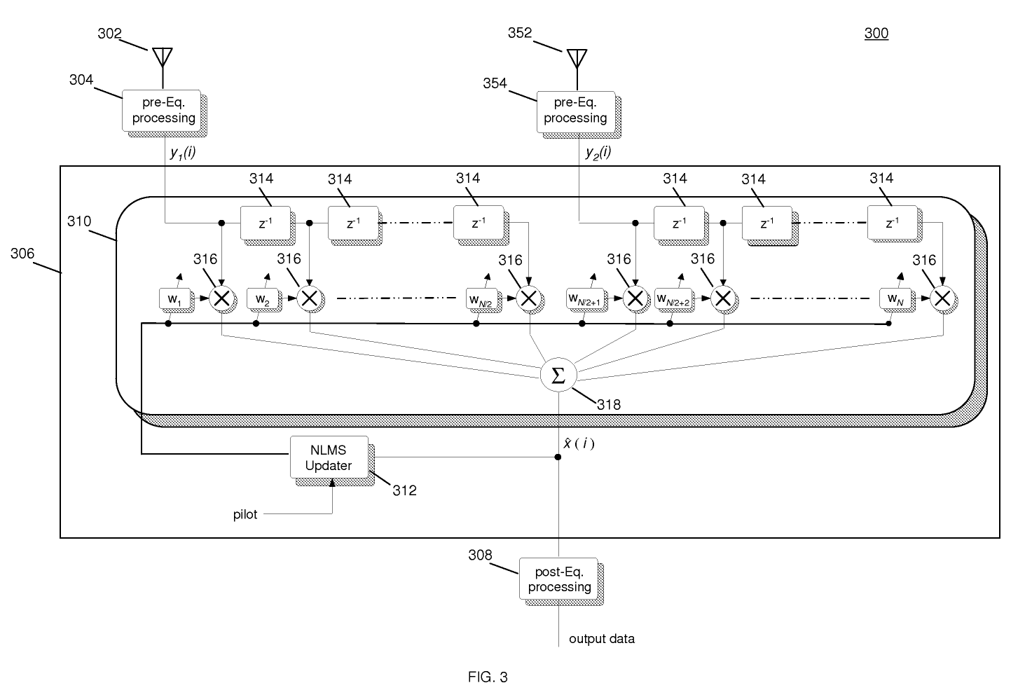

FIG. 3 shows a simplified block diagram of a receiver 300 having two antennas according to one embodiment of the present invention. Antenna 302 receives a first version of a transmitted signal and provides the first version to pre-equalization processing 304. Antenna 352 receives a second version of the transmitted signal, which is transmitted over a propagation path different from that of the first received version, and provides the second version to pre-equalization processing 354. Pre-equalization processing 304 and 354 perform operations analogous those of pre-equalization processing 104 of receiver 100 of FIG. 1 to generate and prepare pre-processed signals y₁(i) and y₂(i), respectively, for equalization. Pre-processed signals y₁(i) and y₂(i) are then provided to equalizer 306, which concatenates the two signals and equalizes the resulting concatenated stream to generate a single equalized signal \hat{x}(i). Equalized signal \hat{x}(i) is then provided to post-equalization processing 308, which performs operations analogous to those of post-equalization processing 108 of receiver 100 to recover one or more output data streams from the received signals.

NLMS equalizer 306 comprises FIR filter 310 and coefficient updater 312. FIR filter 310 has two tapped delay lines, each delay line comprising N/2−1 delay elements 314. Additionally, each tapped delay line corresponds to N/2 multipliers 316, wherein the tapped delay line and the corresponding N/2 multipliers 316, together, can be considered to be a sub-filter. During each iteration, FIR filter 310 processes N/2 samples of pre-processed signal y₁(i) and N/2 samples of pre-processed signal y₂(i) using a set of N NLMS coefficients (i.e., w(i)=w₁(i), w₂(i), . . . ,w_{N}(i)) provided by NLMS coefficient updater 312. Specifically, during each iteration, a new sample of pre-processed signal y₁(i) is applied to the first tapped delay line, such that each sample, excluding the new sample, has been delayed by one or more delay elements 314. Additionally, the N/2 samples of pre-processed signal y₁(i) are provided to the corresponding N/2 multipliers 316, where each multiplier 316 multiplies the corresponding sample by a corresponding NLMS coefficient in a first subset of the set of coefficients (i.e., w₁(i), w₂(i), . . . ,w_{N/2}(i)), and provides the resulting product to summation block 318. At the same time, a new sample of pre-processed signal y₂(i) is applied to the second tapped delay line, the N/2 samples of pre-processed signal y₂(i) are processed in a similar manner using a second subset of the set of coefficients (i.e., w_{N/2+1}(i), w_{N/2+2}(i), . . . ,w_{N}(i)), and the resulting products from the N/2 corresponding multipliers 316 are provided to summation block 318. Summation block 318 then adds the products received from the N multipliers 316 to generate one sample of equalized signal \hat{x}(i).

By the time that an equalized sample is generated, the samples of pre-processed signals y₁(i) and y₂(i) are advanced by one or more delay elements 314 within the corresponding tapped delay lines. The set of NLMS coefficients w(i) received from NLMS coefficient updater 312 is then updated for the next iteration. This process is repeated to equalize further samples of pre-processed signals y₁(i) and y₂(i).

As with NLMS coefficient updater 112 of FIG. 1, the set of NLMS coefficients w(i) is updated by NLMS coefficient updater 312 using an NLMS algorithm. First, during each iteration, an error measure ê(i) is calculated as shown in Equation (2). Then, each updated NLMS coefficient in the set is calculated by substituting pre-processed signal vector y(i), which is the concatenation of vectors y₁(i) and y₂(i), into Equation (3). For example, NLMS coefficient updater 312 generates each coefficient wⱼ(i+1) as shown in Equation (4):

$${w}_{j} ( i + 1 ) = {w}_{j} ( i ) - \tilde{Δ} \frac{{y}_{j} ( i ) {\hat{e}}^{*} ( i )}{{‖ y ( i ) ‖}^{2}} , for j = 1 , … , N \qquad ( 4 )$$

where \tilde{Δ} is a step size, yⱼ(i) is the sample of vector y(i), corresponding to tap j, ∥y(i)∥ is the magnitude of vector y(i), and ê*(i) is the complex conjugate of error measure ê(i). Note that this update equation is identical to that used for a single antenna input.

Receiver 300 concatenates pre-processed signals y₁(i) and y₂(i) and equalizes the concatenated signal to generate one equalized signal \hat{x}(i). In so doing, NLMS coefficient updater 312 generates error measure ê(i), which is representative of the error of the combined signals. Further, this combined error is minimized as NLMS coefficient updater 312 adaptively generates the updated set of coefficients. In contrast, receiver 200 of FIG. 2 does not adaptively minimize the error of concatenated signals. Receiver 200 generates separate equalized signals \hat{x}₁(i) and \hat{x}₂(i) from pre-processed signals y₁(i) and y₂(i), respectively, and reduces the error measure ê(i) of each equalized signal independently. Then equalized signals \hat{x}₁(i) and \hat{x}₂(i) are combined by MRC 226 using parameter estimates that introduce inaccuracies in the combining process. As a result, by minimizing the error of the concatenated signal, receiver 300 is capable of generating more-accurate output data than receiver 200 when the number of filter taps employed by receiver 300 is equal to the total number of filter taps employed by receiver 200 (i.e., when the number of filter taps of equalizer 306 is equal to the number of filter taps of equalizer 206 plus the number of filter taps of 256).

In addition to improvements in reliability, receiver 300 is less complex than receiver 200. Receiver 300 may be implemented using less processing because it does not require duplicate NLMS equalizers, duplicate post-equalization processing blocks, parameter estimation, and MRC combining. Due to the reduced processing, receiver 300 may also perform fewer computations than receiver 200 to equalize pre-processed signals y₁(i) and y₂(i).

According to alternative embodiments of the present invention, each updated NLMS coefficient in the set may be calculated by substituting pre-processed signal vectors y₁(i) or y₂(i) into Equation (3) to generate two update equations. In so doing, NLMS coefficient updater 312 generates each coefficient wⱼ(i+1) in the first half of the set of coefficients (i.e., w₁(i), w₂(i), . . . ,w_{N/2}(i)) as shown in Equation (5):

$${w}_{j} ( i + 1 ) = {w}_{j} ( i ) - \tilde{Δ} \frac{{y}_{1 , j} ( i ) {\hat{e}}^{*} ( i )}{{‖ {y}_{1} ( i ) ‖}^{2}} , for j = 1 , … , N / 2 \qquad ( 5 )$$

and each coefficient in the second half of the set of coefficients (i.e., w_{N/2+1}(i), w_{N/2+2}(i), . . . ,w_{N}(i)) as shown in Equation (6):

$${w}_{j} ( i + 1 ) = {w}_{j} ( i ) - \tilde{Δ} \frac{{y}_{2 , j} ( i ) {\hat{e}}^{*} ( i )}{{‖ {y}_{2} ( i ) ‖}^{2}} , for j = N / 2 + 1 , … , N \qquad ( 6 )$$

where ∥y₁(i)∥ and ∥y₂(i)∥ are the magnitudes of vectors y₁(i) and y₂(i), respectively.

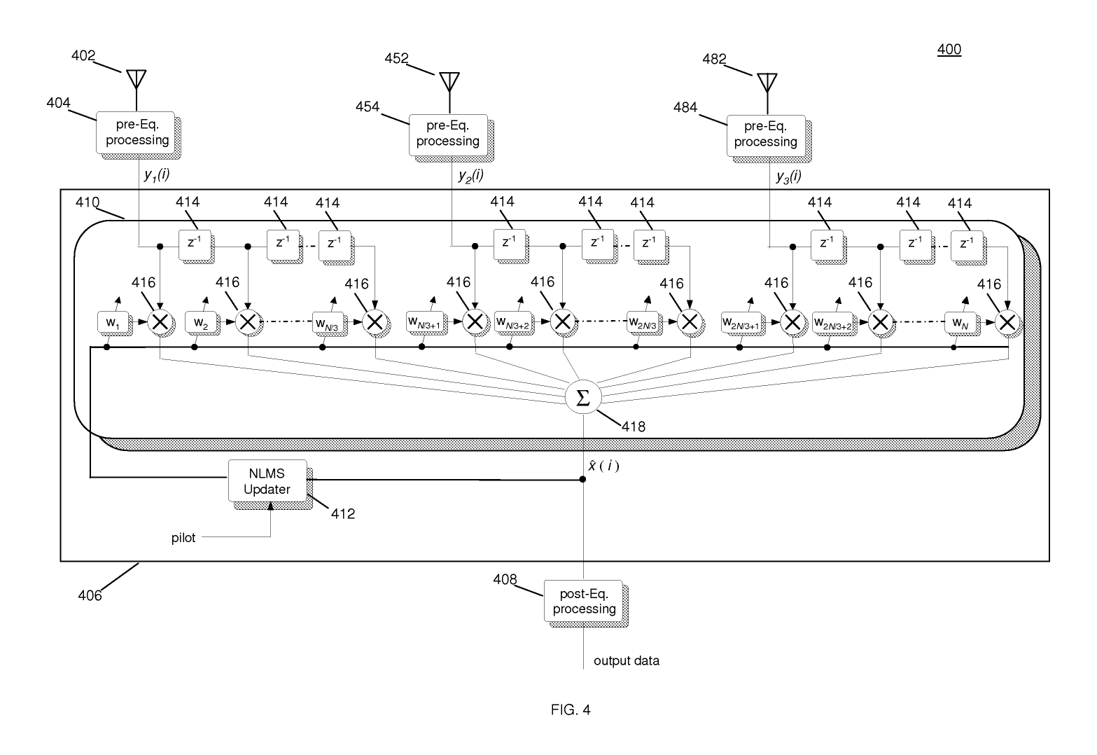

Additional embodiments of the present invention may be envisioned that process three or more versions of a signal. FIG. 4 shows a simplified block diagram of a receiver 400 according to one such embodiment having three antennas 402, 452, and 482. Antennas 402, 452, and 482 provide different versions of the received signal to pre-equalization blocks 404, 454, and 484, respectively, each of which performs operations analogous to those of the equivalent processing of receiver 300. Next, FIR filter 410 processes each received version through a separate sub-filter comprising a tapped delay line with N/3−1 delay elements 414 and N/3 multipliers 416. Each sub-filter performs operations analogous to those of the sub-filters of receiver 300 of FIG. 3. The products generated by the multipliers 416 are then provided to summation block 418 where they are added together to generate a sample of equalized signal \hat{x}(i). In further embodiments, additional versions of the received signal may be processed by adding additional antennas, pre-equalization processing blocks, and sub-filters for each additional received version.

The present invention has been described in the context of multi-sub-filter applications in which two or more versions of the transmitted signal are processed using different subsets of coefficients and multipliers. Certain embodiments of the present invention may also support a single-signal operating mode in which a single version of the transmitted signal is equalized using the two or more adaptive sub-filters as a single adaptive filter.

While the present invention was described using an NLMS equalizer to equalize multiple versions of a received signal, the present invention is not so limited. Alternative embodiments of the present invention may be envisioned in which the receiver employs equalizers other than NLMS equalizers such as an LMS equalizer, a recursive least-squares equalizer, and any other suitable equalizer that adaptively generates filter coefficients. Furthermore, the present invention is not limited to the use of FIR filters. Other filters may be used without departing from the scope of this invention, including but not limited to infinite impulse response (IIR) filters.

While the present invention was described in terms of advancing each received version of a signal through a tapped-delay line, one sample at a time, the present invention may be extended such that each sample is shifted through multiple delay elements of the tapped delay line at a time (e.g., to accommodate oversampling).

The present invention may also be used to equalize multiple versions of a signal that are transmitted over transmission paths other than airwaves. For example, the present invention may be used to equalize multiple versions of a signal transmitted over multiple copper wires, multiple coax cables, or other transmission mediums.

The present invention may be implemented as circuit-based processes, including possible implementation as a single integrated circuit (such as an ASIC or an FPGA), a multi-chip module, a single card, or a multi-card circuit pack. As would be apparent to one skilled in the art, various functions of circuit elements may also be implemented as processing blocks in a software program. Such software may be employed in, for example, a digital signal processor, micro-controller, or general-purpose computer.

The present invention can be embodied in the form of methods and apparatuses for practicing those methods. The present invention can also be embodied in the form of program code embodied in tangible media, such as magnetic recording media, optical recording media, solid state memory, floppy diskettes, CD-ROMs, hard drives, or any other machine-readable storage medium, wherein, when the program code is loaded into and executed by a machine, such as a computer, the machine becomes an apparatus for practicing the invention. The present invention can also be embodied in the form of program code, for example, whether stored in a storage medium, loaded into and/or executed by a machine, or transmitted over some transmission medium or carrier, such as over electrical wiring or cabling, through fiber optics, or via electromagnetic radiation, wherein, when the program code is loaded into and executed by a machine, such as a computer, the machine becomes an apparatus for practicing the invention. When implemented on a general-purpose processor, the program code segments combine with the processor to provide a unique device that operates analogously to specific logic circuits. The present invention can also be embodied in the form of a bitstream or other sequence of signal values electrically or optically transmitted through a medium, stored magnetic-field variations in a magnetic recording medium, etc., generated using a method and/or an apparatus of the present invention.

It will be further understood that various changes in the details, materials, and arrangements of the parts which have been described and illustrated in order to explain the nature of this invention may be made by those skilled in the art without departing from the scope of the invention as expressed in the following claims.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the present invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

We claim:

1. A method for equalizing two or more versions of a signal transmitted through two or more different transmission paths, the method comprising:
(a) applying two or more adaptive sub-filters to the two or more versions to generate two or more sub-filtered signals;
(b) combining the two or more sub-filtered signals to generate an equalized output signal for the two or more versions; and
(c) updating the two or more adaptive sub-filters based on the equalized output signal.

2. The invention of claim 1, wherein:
for step (a), applying each adaptive sub-filter comprises multiplying one version of the two or more versions by a subset of coefficients; and
for step (c), updating the two or more adaptive sub-filters comprises:
(1) calculating an error measure for the equalized output signal; and
(2) updating each subset of coefficients based on the error measure.

3. The invention of claim 2, wherein each subset of coefficients is updated using a normalized-least-mean-squares algorithm.

4. The invention of claim 3, wherein:
the two or more subsets of coefficients comprise N coefficients wⱼ(i);
each coefficient wⱼ(i) is updated as follows:
$${w}_{j} ( i + 1 ) = {w}_{j} ( i ) - \tilde{Δ} \frac{{y}_{j} ( i ) {\hat{e}}^{*} ( i )}{{‖ y ( i ) ‖}^{2}} , for j = 1 , … , N ;$$
\tilde{Δ} is a step size;
N is a positive even integer;
y(i) is a vector representing a concatenation of the two or more versions of the signal;
yⱼ(i) is a jth element of the vector y(i);
∥y(i)∥ is a magnitude of the vector y(i); and
ê*(i) is a complex conjugate of the error measure ê(i).

5. The invention of claim 1, wherein each version is received using a different antenna.

6. The invention of claim 1, wherein:
step (a) further comprises, for each of one or more additional versions of the signal, applying an additional adaptive sub-filter to the additional version to generate an additional sub-filtered signal;
step (b) further comprises combining the two or more sub-filtered signals and the one or more additional sub-filtered signals to generate the equalized output signal; and
step (c) further comprises updating each additional adaptive sub-filter based on the equalized output signal.

7. An apparatus for equalizing two or more versions of a signal transmitted through two or more different transmission paths, the apparatus comprising:
(a) two or more adaptive sub-filters adapted to generate two or more sub-filtered signals from the two or more versions;
(b) a combining block adapted to combine the two or more sub-filtered signals to generate an equalized output signal for the two or more versions; and
(c) a coefficient updater adapted to update the two or more adaptive sub-filters based on the equalized output signal.

8. The invention of claim 7, wherein:
each adaptive sub-filter comprises multipliers adapted to multiply samples of one version of the two or more versions by a subset of coefficients; and
the coefficient updater is adapted to update the two or more adaptive sub-filters by:
(1) calculating an error measure of the equalized output signal; and
(2) updating each subset of coefficients based on the error measure.

9. The invention of claim 8, wherein the coefficient updater updates each subset of coefficients using a normalized-least-mean-squares (NLMS) algorithm.

10. The invention of claim 9, wherein:
the two or more subsets of coefficients comprise N coefficients wⱼ(i);
each coefficient wⱼ(i) is updated as follows:
$${w}_{j} ( i + 1 ) = {w}_{j} ( i ) - \tilde{Δ} \frac{{y}_{j} ( i ) {\hat{e}}^{*} ( i )}{{‖ y ( i ) ‖}^{2}} , for j = 1 , … , N ;$$
\tilde{Δ} is a step size;
N is a positive even integer;
y(i) is a vector representing a concatenation of the two or more versions of the signal;
yⱼ(i) is a jth element of the vector y(i);
∥y(i)∥ is a magnitude of the vector y(i); and
ê*(i) is a complex conjugate of the error measure ê(i).

11. The invention of claim 7, wherein each version is received using a different antenna.

12. The invention of claim 7, wherein:
the apparatus further comprises one or more additional adaptive sub-filters adapted to generate one or more additional sub-filtered signals from one or more additional versions of the signal;
the combining block is further adapted to combine the two or more sub-filtered signals and the one or more additional sub-filtered signals to generate the equalized output signal; and
the coefficient updater is further adapted to update each additional adaptive sub-filter based on the equalized output signal.

13. The invention of claim 7, wherein the apparatus supports a single-signal operating mode in which a single version of the transmitted signal is equalized using the two or more adaptive sub-filters as a single adaptive filter.

14. A method for equalizing at least a first and a second version of a signal transmitted through two or more different transmission paths, the method comprising:
(a) filtering the first version based on a first subset of filter coefficients and the second version based on a second subset of filter coefficients to generate an equalized signal;
(b) calculating an error measure based on the equalized signal; and
(c) adaptively updating the first and second subsets of filter coefficients based on the error measure.

15. The invention of claim 14, wherein step (a) comprises:
(a1) multiplying samples of each version of the transmitted signal by the corresponding subset of filter coefficients, wherein, for each version, each sample is multiplied by one coefficient of the corresponding subset to generate a product; and
(a2) combining the products generated from the at least first and second versions to generate a sample of the equalized signal.

16. The invention of claim 15, wherein step (a) further comprises repeating steps (a1) and (a2) to generate further samples of the equalized signal.

17. The invention of claim 14, wherein, for step (c), the first and second subset of filter coefficients are adaptively updated using a normalized-least-mean-squares (NLMS) algorithm.

18. The invention of claim 17, wherein:
the two or more subsets of coefficients comprise N coefficients wⱼ(i);
each coefficient wⱼ(i) is updated as follows:
$${w}_{j} ( i + 1 ) = {w}_{j} ( i ) - \tilde{Δ} \frac{{y}_{j} ( i ) {\hat{e}}^{*} ( i )}{{‖ y ( i ) ‖}^{2}} , for j = 1 , … , N ;$$
\tilde{Δ} is a step size;
N is a positive even integer;
y(i) is a vector representing a concatenation of the two or more versions of the signal;
yⱼ(i) is a jth element of the vector y(i);
∥y(i)∥ is a magnitude of the vector y(i); and
ê*(i) is a complex conjugate of the error measure ê(i).

19. The invention of claim 14, wherein each version is received using a different antenna.

20. The invention of claim 14, wherein:
step (a) further comprises filtering one or more additional versions of the signal based on one or more additional subsets of filter coefficients to generate the equalized signal; and
step (c) further comprises adaptively updating each additional subset of coefficients based on the error measure.

21. An apparatus for equalizing at least a first and a second version of a signal transmitted through two or more different transmission paths, the apparatus comprising:
(a) a filter adapted to filter the first version based on a first subset of filter coefficients and the second version based on a second subset of filter coefficients to generate an equalized signal;
(b) an error calculator adapted to calculate an error measure based on the equalized signal; and
(c) a coefficient updater adapted to adaptively update the first and second subsets of filter coefficients based on the error measure.
